(19) United States
(12) Patent Application Publication
(10) Pub. No.: US 2023/0086109 A1
(43) Pub. Date: Mar. 23, 2023

(54) CBRAM BOTTOM ELECTRODE STRUCTURES

(71) Applicant: Dialog Semiconductor US Inc., Santa Clara, CA (US)

(72) Inventors: John R. Jameson, Menlo Park, CA (US); Kuei-Chang Tsai, San Jose, CA (US)

(21) Appl. No.: 17/879,904

(22) Filed: Aug. 3, 2022

Related U.S. Application Data
(60) Provisional application No. 63/247,412, filed on Sep. 23, 2021.

(51) Int. Cl. H01L 45/00; H01L 27/24

(52) U.S. Cl. CPC H01L 45/1266; H01L 27/2463; H01L 45/085; H01L 45/1233; H01L 45/145; H01L 45/1675

(57) ABSTRACT

A method of forming bottom electrodes in a resistive memory device, can include: depositing a bottom insulator on a substrate ILD; forming vias in the substrate by patterning and etching holes in the bottom insulator and the substrate ILD; filling the holes with a via metal to form a flat via surface; depositing a bottom electrode thin film and a top insulator; defining the bottom electrode; etching the top insulator, the bottom electrode thin film, and the bottom insulator; depositing a cell plate layer having a switching layer, an anode layer, and a cap layer; patterning the cell plate layer by depositing and patterning a cell plate hard mask layer, and then etching the cell plate layer; encapsulating the cell plate layer; and forming electrical contact to the cell plate layer.

### RELATED APPLICATIONS

This application claims the benefit of U.S. Provisional Application No. 63/247,412, filed Sep. 23, 2021, and which is incorporated herein by reference in its entirety.

### FIELD OF THE INVENTION

The present invention generally relates to the field of semiconductor devices. More specifically, embodiments of the present invention pertain to memory devices, including both volatile and non-volatile memory devices, such as flash memory devices, resistive random-access memory (ReRAM), and/or conductive bridging RAM (CBRAM) processes and devices.

### BACKGROUND

Non-volatile memory (NVM) is increasingly found in applications, such as solid-state hard drives, removable digital picture cards, and so on. Flash memory is the predominant NVM technology in use today. However, flash memory has limitations, such as a relatively high programming current, as well as physical degradation of the memory cell over time. Other NVM technologies, such as resistive RAM (ReRAM) and conductive bridging RAM (CBRAM), may offer relatively low power and higher speeds as compared to flash memory technologies. CBRAM utilizes a programmable metallization cell (PMC) technology, which has the potential to scale to smaller sizes than flash memory devices.

### BRIEF DESCRIPTION OF THE DRAWINGS

FIG. 1 is an example memory device arrangement.

FIG. 2 is a diagram of an example memory device and memory cell structure.

FIG. 3 is a diagram of an example programmable impedance element with schematic modeling.

FIG. 4 is a diagram of an example bottom electrode structure.

FIG. 5 is a diagram of an example edge bottom electrode structure, in accordance with embodiments of the present invention.

FIGS. 6A-6K are cross-section diagrams of an example process flow for making an edge bottom electrode structure, in accordance with embodiments of the present invention.

FIG. 7 is a diagram of an example bottom electrode structure without a bottom insulator, in accordance with embodiments of the present invention.

FIG. 8 is a diagram of an example rectangular/dumbbell bottom electrode structure, in accordance with embodiments of the present invention.

FIG. 9 is a diagram of an example square bottom electrode structure, in accordance with embodiments of the present invention.

FIG. 10 is a diagram of an example sidewall bottom electrode structure, in accordance with embodiments of the present invention.

FIG. 11 is a diagram of an example structure corresponding to a layout of the sidewall bottom electrode structure, in accordance with embodiments of the present invention.

FIG. 12 is a diagram of an example process flow of the sidewall bottom electrode structure, in accordance with embodiments of the present invention.

FIG. 13 is a cross-sectional diagram of the example sidewall bottom electrode structure, in accordance with embodiments of the present invention.

### DETAILED DESCRIPTION OF EMBODIMENTS

Reference will now be made in detail to particular embodiments of the invention, examples of which are illustrated in the accompanying drawings. While the invention will be described in conjunction with the preferred embodiments, it will be understood that they are not intended to limit the invention to these embodiments. On the contrary, the invention is intended to cover alternatives, modifications and equivalents that may be included within the spirit and scope of the invention as defined by the appended claims. Furthermore, in the following detailed description of the present invention, numerous specific details are set forth in order to provide a thorough understanding of the present invention. However, it will be readily apparent to one skilled in the art that the present invention may be practiced without these specific details. In other instances, well-known methods, procedures, processes, components, structures, and circuits have not been described in detail so as not to unnecessarily obscure aspects of the present invention.

Some portions of the detailed descriptions which follow are presented in terms of processes, procedures, logic blocks, functional blocks, processing, schematic symbols, and/or other symbolic representations of operations on data streams, signals, or waveforms within a computer, processor, controller, device, and/or memory. These descriptions and representations are generally used by those skilled in the data processing arts to effectively convey the substance of their work to others skilled in the art. Usually, though not necessarily, quantities being manipulated take the form of electrical, magnetic, optical, or quantum signals capable of being stored, transferred, combined, compared, and otherwise manipulated in a computer or data processing system. It has proven convenient at times, principally for reasons of common usage, to refer to these signals as bits, waves, waveforms, streams, values, elements, symbols, characters, terms, numbers, or the like.

Particular embodiments may be directed to programmable metallization cells (PMC). Examples of such cells are shown and described in U.S. Pat. Nos. 6,635,914 and 7,359,236. The invention, in its various aspects, will be explained in greater detail below with regard to exemplary embodiments. The embodiments show structures and methods of operating PMCs that can be programmed/written and erased between one or more resistance and/or capacitive states.

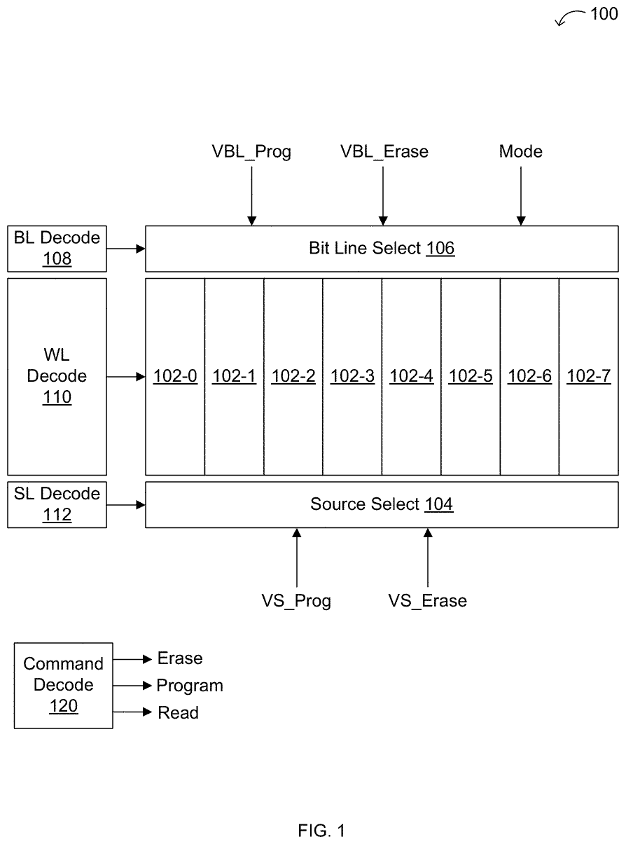

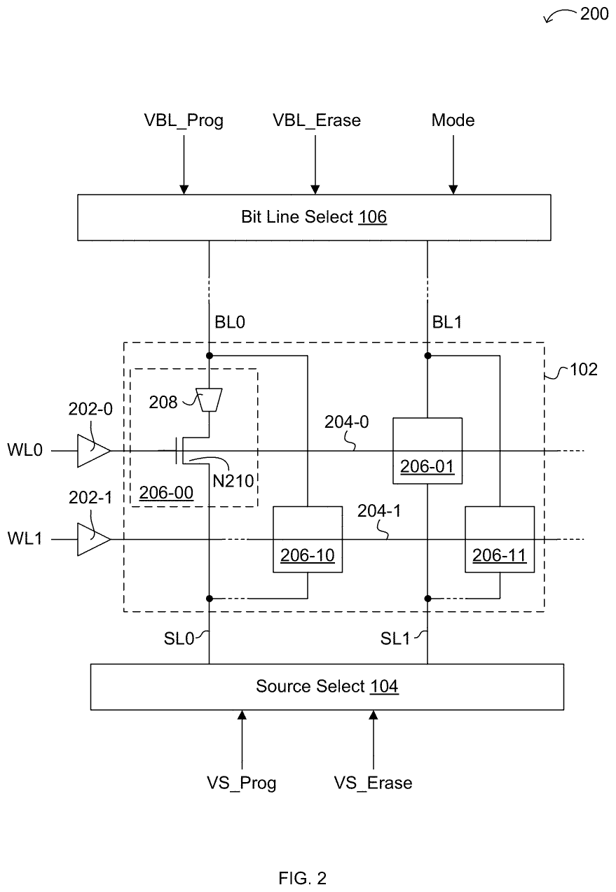

FIGS. 1 and 2 show example memory architectures and circuit structures that can utilize PMCs of particular embodiments. However, PMCs of particular embodiments are suitable for use in a wide variety of memory architectures and circuit structures.

Referring now to FIG. 1, an example memory device is shown and designated by the general reference character 100. A memory device 100 can include PMC sectors 102-0 to 102-7, source node selection circuitry 104, bit line selection circuitry 106, bit line decoding circuitry 108, word line decoding circuitry 110, and source line decoding circuitry 112. A memory device 100 can be a single integrated circuit or form a portion of a larger integrated circuit device that provides functions in addition to memory, such as in an “embedded” memory configuration.

FIG. 1 may also include command decoding circuitry 120. For example, command decoding circuitry 120 may receive external signals, or control signals derived therefrom, and may generate various internal control signals (e.g., program, erase, read, etc.) in response. Such internal operation control signals can be used to generate various supply levels (e.g., particular program and erase voltage levels), as well as other control signals (e.g., program or erase operation control signals), as will be discussed in more detail below. In this way, command decoding circuitry 120 may be used to determine an operation to be performed on the device.

PMC sectors (102-0 to 102-7) can each include a number of memory cells arranged into one or more columns and multiple rows. Each memory cell can include one or more PMCs and a selection device. Generally, a PMC may be configured such that when a bias greater than a threshold voltage (Vt_{PMC}) is applied across electrodes of the PMC, the electrical properties of the PMC can change. For example, in some arrangements, as a voltage is applied across the electrodes of the PMC, conductive ions within an ion conductor may begin to migrate and form an electrodeposit at or near the more negative of the electrodes. Such an electrodeposit, however, is not required to induce a change in electrical properties. The term “electrodeposit” as used herein means any area within the ion conductor that has an increased concentration of reduced metal or other conductive material compared to the concentration of such material in the bulk ion conductor material. As the electrodeposit forms, the resistance between the electrodes can decrease, and other electrical properties may also change. If a voltage is applied in reverse, the electrodeposit can dissolve back into the ion conductor and a device can return to a former electrical state (e.g., high resistance state).

In particular arrangements, one electrode of a PMC can be formed of a material including a metal that dissolves in the ion conductor when a sufficient bias is applied across the electrodes (oxidizable electrode), and the other electrode is relatively inert and does not dissolve during operation of the programmable device (an indifferent or “inert” electrode). For example, one electrode may be an anode during a write process and be comprised of a material including silver that dissolves in an ion conductor while another electrode may be a cathode during the write process and be comprised of an inert material, such as tungsten, nickel, molybdenum, platinum, metal silicides, and the like. Having at least one electrode formed of a material including a metal which dissolves in an ion conductor can facilitate maintaining a desired dissolved metal concentration within an ion conductor, which in turn, can facilitate rapid and stable electrodeposit formation within ion conductor or other electrical property change during use of a PMC. Furthermore, use of an inert material for the other electrode (cathode during a write operation) can facilitate electrodissolution of any electrodeposit that may have formed and/or return of the programmable device to an erased state after application of a sufficient voltage.

Referring still to FIG. 1, in the particular example shown, PMC sectors (102-0 to 102-7) can have a “bit line anode” configuration. That is, for each given memory cell, the anode of the corresponding PMC(s) can be connected to a bit line by a conductive connection that does not include the corresponding access device. Each such bit line may provide a read data path for the corresponding PMC. This represents just one example PMC architecture, and is in contrast to other PMC memory device architectures that have bit lines connected to a corresponding PMC via the access device of the cell. As noted above, PMCs in particular embodiments are suitable for use in any type of PMC memory device architecture.

PMC sectors (102-0 to 102-7) may also have a “strapped source line” architecture. Within each PMC sector, groups of access devices within each memory cell can have terminals formed by diffusions in an integrated circuit substrate. Groups of such diffusions can be “strapped” by a low resistance structure that provides a conductive connection between groups of such diffusion regions. Such an arrangement can be in contrast to a PMC architecture in which access devices may be directly connected to a bit line. Also, while eight PMC sectors (102-0 to 102-7) are shown in the particular example of FIG. 1, other examples may include fewer or greater numbers of PMC sectors. In FIG. 1, source node selection circuitry 104 can selectively connect source straps to various nodes depending upon the mode of operation and a source decoding value. In one particular example, source node selection circuitry 104 can connect a selected source strap between at least two different voltages, depending on whether the device is operating in a program operation or read operation, or in an erase operation.

Voltages VBL_Prog, VBL_Erase, VS_Prog, and VS_Erase may be generated power supply voltages, such +5 and 0 volts, or +3.3 and 0 volts, or +1.2 and 0 volts. In one example, such voltages may be one or more power supply voltages received at an external pin of an integrated circuit including memory device 100. In another example, such voltages may be one or more voltages generated by a voltage generator (e.g., based on a reference voltage) of an integrated circuit that includes memory device 100. In any event, such voltages may be used, either directly or indirectly, for programming (e.g., in a forward bias configuration) or erasing (e.g., in a reverse bias configuration) a PMC by applying suitable voltages across the electrodes thereof.

Bit line selection circuitry 106 can selectively connect bit lines of one or more PMC sections (102-0 to 102-7) according to a mode of operation and bit line decoding values. In one particular example, bit line selection circuitry 106 can advantageously connect a selected bit to either of voltages VBL_Prog or VBL_Erase. That is, in a program operation, a selected bit line can be connected to voltage VBL_Prog, while in an erase operation, a selected bit line can be connected to voltage VBL_Erase.

Bit line selection circuitry 106, similar to source selection circuitry 104, can connect bit lines to an inhibit voltage for PMCs that are not selected for erase or program. It is noted that an arrangement like that shown in FIG. 1 can advantageously provide program and erase voltages without having to include charge pumps or the like, to a voltage that is outside a power supply range, as may exist in other approaches. Instead, supply voltages applied across a selected PMC device can be switched between program and erase operations. In this way, program and erase can be “symmetric” operations. That is, in a programming operation, a PMC to be programmed can be connected between suitable voltages (e.g., V1−V2) in an anode-to-cathode direction. In an erase operation, a PMC to be erased can be connected between suitable voltages (e.g., V2−V1) in an anode-to-cathode direction.

In this example, voltages V1 and V2 (not shown in FIG. 1) may be applied as one or more of voltages VBL_Prog, VBL_Erase, VS_Prog, and VS_Erase. This is in contrast to architectures that maintain a constant voltage on anodes of PMCs, and then provide program and erase voltages with respect to such a common anode voltage. In such a case, a supply voltage must be equal to a program voltage plus an erase voltage (Vprog+Verase). However, in a symmetric operation according to an embodiment, a program voltage may be an erase voltage, which may both be a supply voltage (Vprog=V1−V2, Verase=V2−V1, Supply voltage=V2−V1). In any event, a suitable voltage may be applied across a PMC in order to program the cell, and a reverse such voltage may be applied across the PMC in order to erase the cell.

Bit line decoding circuitry 108 can generate values for selecting given bit lines for read, program, and erase operations. In one arrangement, in response to address information (e.g., column address data), bit line decoding circuitry 108 can generate bit line select signals for application to bit line select circuitry 106.

Word line decoding circuitry 110 can generate values for selecting a given set of memory cells by enabling access devices in one or more selected rows of PMC sections (102-0 to 102-7). In response to address information (e.g., row address data), one or more word lines can be driven to a select voltage to thereby enable the corresponding select device (e.g., a transistor) in a row of memory cells. In this way, the PMCs of the selected row can be connected to a source node. Word lines can extend in a direction different than (e.g., essentially perpendicular to) the source straps.

Source decoding circuitry 112 can generate values for selecting given source straps. In one arrangement, in response to address information (e.g., column address data), source decoding circuitry 112 can generate source select signals for application to source node select circuitry 104. Source decoding circuitry 112 can select a source strap corresponding to a same memory cell as a selected bit line, and thereby enable a program, read, or erase operation.

In this way, a memory device can include PMCs as data storage elements with anodes commonly connected to bit lines and memory cell access devices connected to strapped and decoded sources. Such select circuitry can also provide for symmetrical program and erase operations utilizing bit line decoding and source strap decoding.

Referring now to FIG. 2, shown is a schematic block diagram of an example memory device and memory cell structure, as designated by the general reference character 200. Memory device 200 can be one implementation of the example shown in FIG. 1. Memory device 200 includes a PMC sector 102 that is shown for illustration purposes by four memory cells (e.g., 206-00, 206-10, 206-01, and 206-11), arranged into four columns and two rows (e.g., corresponding to WL0 and WL1). Two memory cells are shown connected to each of two bit lines BL0 and BL1. It is understood that the arrangement can be repeated to form a much larger memory cell array structure. Each memory cell (e.g., 206-00 to 206-11) can include a PMC 208 and an access device N210, which in this example is an n-channel insulated gate field effect (hereinafter “MOS”) transistor. It is noted that while FIG. 2 shows an arrangement in which one PMC is provided per memory cell, alternate embodiments may include more than one PMC per memory cell.

PMCs 208 may have a structure as described in conjunction with FIG. 1, or equivalents. In the particular example of FIG. 2, PMC sector 102 also includes word line drivers 202-0 and 202-1. Word line drivers 202-0 and 202-1 can drive corresponding word lines 204-0 and 204-1 high to thereby select a memory cell 206, thus placing its corresponding access device (e.g., N210) into a low impedance state.

Read/write control circuitry within bit line selection circuitry 106 can vary in operation according to mode values. In a program operation, a read/write circuit can connect a selected bit line to an anode program voltage. In an erase operation, a read/write circuit can connect a selected bit line to an anode erase voltage. In a read operation, a read/write circuit can connect a selected bit line to a read bias voltage. Source line selection circuitry 104 can connect one or more of corresponding source straps (e.g., SL0 and SL1) to a source program voltage (VS_Prog), a source erase voltage (VS_Erase), or to a source de-select state. The source de-select state can be a high impedance state in the case of an “isolated” bit line architecture, or alternatively, can be a de-select bias voltage, in the case of a de-select bias architecture. Source line selection circuitry 104 can vary the number of source straps commonly driven to a same state. That is, source line selection circuitry 104 can select source straps connected to but one column of memory cells, or connected to multiple such columns.

Having described the various sections of FIG. 2, one example of the operation of such a memory device will now be described with reference to an operation that accesses memory cell 206-00. Initially, word lines 204 can be driven to a de-select voltage (e.g., low) by word line drivers 202. Bit line selection circuitry 106 can place bit lines BL0 and BL1 in the de-selected state. Similarly, source line selection circuitry 104 can place source straps SL0 and SL1 in the de-select state.

In a program operation (which may be part of a sequence of operations in a program “algorithm”), in response to address and mode data, bit line selection signals can be used to connect bit line BL0 to read/write control circuitry. In contrast, bit line BL1 can be de-selected, and thus placed in the de-selected state. Mode selection values can result in read/write control circuitry connecting the selected bit line (e.g., BL0) to an anode program voltage. A program operation can also include source selection signals connecting source strap SL0 to a source program voltage (e.g., VS_Prog), while connecting source strap SL1 to a source de-select state. A word line driver (e.g., 202-0) corresponding to the selected memory cell can be driven to a select voltage, thereby placing the selected PMC (e.g., PMC 208 of memory cell 206-00) between suitable programming voltages.

An erase operation (which may be part of a sequence of operations in an erase “algorithm”) can occur in the same general fashion, but with the erase voltage being applied to the selected bit line and source erase voltage (e.g., VS_Erase) being applied to a selected source strap. As noted in the example of FIG. 1, in particular embodiments, such an operation can be symmetrical, such that the anode programming voltage equals VS_Erase, and the anode erase voltage equals VS_Prog. Also, while FIG. 2 shows n-channel MOS transistors as access devices, other embodiments may include different types of access devices. In such alternate embodiments, word line drivers 202 would provide appropriate voltages and/or currents to enable such access devices. In this way, bit line selection, source selection, and word line activation can be utilized to program and/or erase a PMC array having bit lines connected to anodes of PMCs within multiple memory cells.

While particular example architectures and circuits suitable for PMCs, and memory arrays formed thereof, with respect to FIGS. 1 and 2, programmable impedance elements in certain embodiments are suitable to a wide variety of architectures and/or circuit arrangements.

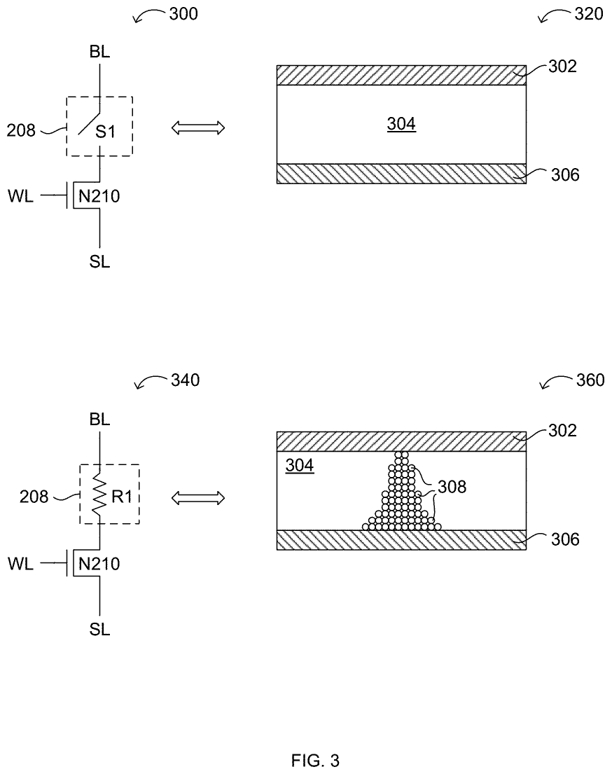

Referring now to FIG. 3, shown is a diagram of an example programmable impedance element with corresponding schematic modeling. Example 300 shows a memory cell with an open switch 51 representation of PMC 208. The PMC portion of this representation corresponds to the cross-section diagram 320, which represents a PMC or programmable impedance element in a high impedance state (e.g., state “0”), or an erased state. Partially dissolved or erased states may also be detected as a data state “0,” or a multi-bit value, in some applications, and depending on the read-trip point. As used herein, “PMC” may be one example of a “programmable impedance element.” In this example, PMC 320 can include electrochemically active electrode 302, solid electrolyte 304, and inert electrode 306.

Schematic representation 340 and corresponding cross-section diagram 360 show examples of PMC 208 in a low impedance state (e.g., state “1”), or a programmed state. Partial conductive paths may also be detected as a data state “1,” or a multi-bit value, in some applications, and depending on the read-trip point. Example 340 shows a memory cell with a resistor R1 or closed switch representation of PMC 208. The PMC portion of this representation corresponds to the cross-section diagram 360. In the example 360, electrodeposits 308 can form in solid electrolyte 304 to form a “bridge” or conductive path between electrochemically active electrode 302 and inert electrode 306. For example, electrodeposits 308 can be from active electrode 302, and may include silver. As shown in examples 300 and 340, a control transistor (e.g., N210) can also be included in each memory cell including the programmable impedance element or PMC 208. For example, transistor N210 can be controlled by a word line 204, as discussed above with respect to FIG. 2.

PMC is based on a physical re-location of ions within a solid electrolyte (e.g., 304). A PMC memory cell or programmable impedance element may be formed of two solid metal electrodes 302 and 306, one relatively inert (e.g., 306) and the other electrochemically active (e.g., 302), with a relatively thin film of the electrolyte (e.g., 304) between the electrodes. As shown in the cross-section diagrams herein, however, the solid electrolyte layer is shown as thicker than the electrodes for illustration purposes.

Solid electrolyte 304 can include a chalcogenide compound, such as a germanium selenium (Ge—Se) compound. Solid electrolyte 304 can be formed by photodissolution of metal into a chalcogenide base glass. Chalcogenide materials are chemical compounds consisting of at least one chalcogen ion (a chemical element in column VI of the periodic table, also known as the oxygen family). More precisely, the term chalcogenide refers to the sulphides, selenides, and tellurides. PMCs may utilize the ionic conduction of compounds containing metallic ions.

Certain metals can be added to thin films of chalcogenide glasses by photodissolution. When Ag is combined in this fashion with Ge—Se or Ge—S glasses, the resulting ternary may contain a dispersed nanocrystalline Ag₂S(e) phase that has relatively large quantities of mobile metal ions. The presence of these ions allows the ternaries to act as solid electrolytes. If an anode that has an oxidizable form of the ionic metal and an inert cathode are applied in contact with such a phase-separated electrolyte, an ion current of mobile elements (e.g., positively charged metal ions) can flow under an applied voltage bias. Electrons from the cathode can reduce the excess metal due to the ion flux and an electrodeposit (e.g., 308) forms on or in the electrolyte (e.g., 304). Also, other materials, such as certain oxides (e.g., tungsten oxide, hafnium oxide, nickel oxide, titanium oxide, transition metal oxides, etc.), can be used, as opposed to Ge—S and Ge—Se chalcogenide glasses. In addition, other metals, such as copper, can be used in place of silver, for the electrochemically active electrode that supplies mobile ions.

Various materials can be utilized to form electrodes 302 and 306. For example, inert electrode 306 can include tungsten, and electrochemically active electrode 302 can include silver or copper. In operation, when a negative bias is applied to inert electrode 306, metal ions in solid electrolyte 304, as well as some originating from the now-positive active electrode 302, can flow in solid electrolyte 304, and are reduced or converted to atoms by electrons from inert electrode 306. After a relatively short period of time, the ions flowing into the filament form a small metallic effective “nanowire” or conductive path between the two electrodes. Such a nanowire can lower the resistance along the conductive path between electrodes 302 and 306, as represented by the open switch model in schematic 300 and the resistor model in schematic 340. Also, the lowered resistance across electrodes 302 and 306 can be measured to indicate that the writing or programming process is complete.

Such a nanowire may not be a continuous wire, but rather a chain of electrodeposit islands or nanocrystals (electrodeposits) 308. A conductive path between the electrodes may appear as more of the chain of electrodeposits under certain operating conditions, particularly at relatively low programming currents (e.g., less than about 1 μA). However, higher programming currents can lead to a mostly metallic conductor or conduction path. Also, and as discussed above, reading the cell data can include switching on the control transistor (e.g., N210), and applying a relatively small voltage across the cell. If a nanowire is in place in that cell (e.g., 360), the resistance can be relatively low, leading to higher current, and that can be read as a “1” data value stored in that cell. However, if there is no nanowire or conductive path between electrodes in the cell (e.g., 320), the resistance is higher, leading to low current, and that can be read as a “0” data value stored in that cell.

Cell data can be erased in similar fashion to cell writing or programming, but with a positive bias on the inert electrode. The metal ions will then migrate away from the filament, back into the electrolyte, and eventually to the negatively-charged active electrode (e.g., 302). This action dissolves the electrodeposits 308 in solid electrolyte 304, and increases the resistance again (e.g., as shown in schematic representation 300). In this way, an erase operation of a PMC can be substantially symmetric to a program or write operation.

Thus in conductive bridging random-access memory (CBRAM) applications, metal ions can dissolve readily in the material (e.g., 304) between the two electrodes (e.g., 302 and 306). In contrast, in resistive RAM (ReRAM) applications, the material between the electrodes may require a high electric field that can cause local damage in may produce a trail of conducting defects (a “filament”). Thus, for CBRAM, one electrode provides the dissolving ions, while for ReRAM, a one-time “forming” step may be required to generate the local damage.

### Example CBRAM Bottom Electrode Structures

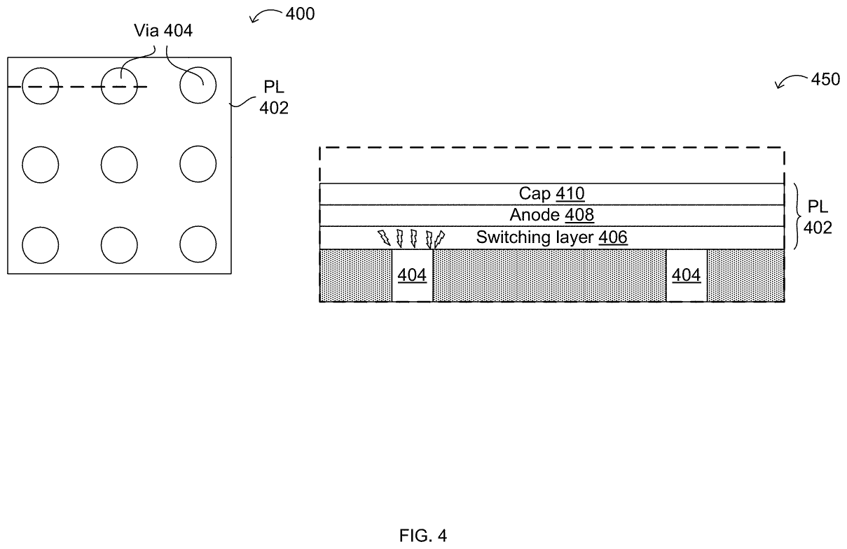

Referring now to FIG. 4, shown is a diagram of an example bottom electrode structure. In this example, 400 shows a top view diagram of the cell plate layer (PL) 402 and via 404 arrangement, while example 450 shows a cross-section diagram. For example, PL 402 can include switching layer 406, anode 408, and cap 410. In one approach for constructing a CBRAM cell, the top of via (e.g., Ta) 404 can be used as the bottom electrode (BE) of the CBRAM cell. However, this may result in difficulty inserting the CBRAM process into new wafer fabrication facilities that do not support a process for making Ta vias, difficulty in exploring alternate bottom electrode materials for continued CBRAM development (e.g., due partly development of a via process, such as including chemical mechanical polishing [CMP], for any new BE material of interest), and sensitivity of CBRAM cell performance to any process steps affecting the shape of the Ta via (e.g., CMP of the Ta, sputter cleaning of the Ta via surface prior to deposition of the CBRAM layers, etc.).

In particular embodiments, a CBRAM cell structure can include a BE of the cell having a BE thin film, and the active area of the cell (i.e., where switching occurs) including one or more lateral edges of this thin film. In certain embodiments, a via process may not be needed to form the BE, and the active area of the BE can be defined without subjecting the active area to CMP (e.g., by etching the BE thin film). Also, the top surface of the BE thin film can be covered with an insulator (“top insulator”), which can be formed by depositing a thin insulating film on top of the BE thin film prior to etching the BE thin film. The top insulator may force the switching to occur at the lateral edge(s) of the BE thin film, and can also prevent shorting of the CBRAM cell between the top and bottom surfaces of the BE thin film during program and/or erase operations. Shorting during erase is known to be a major endurance limiter for many CBRAM designs. The bottom surface of the BE thin film may also be covered with an insulator (“bottom insulator”), which can be achieved, e.g., by depositing the BE thin film on top of an interlayer dielectric (ILD). Like the top insulator, the bottom insulator may force etching to occur at the lateral edge(s) of the BE thin film.

In particular embodiments, the top insulator and the bottom insulator materials may differ from one another in some cases. In such a case, the bottom insulator can be a deposited film that differs from the ILD underneath, and the top insulator may be used as a hard mask to etch the BE. As will be discussed in more detail below, different BE shapes (e.g., round, dumbbell, rectangle, square, etc.) can be supported in certain embodiments. Further, the BE thin film can be coplanar with the wafer, or may be perpendicular, such as can be made by a spacer process, as will also be discussed in more detail below.

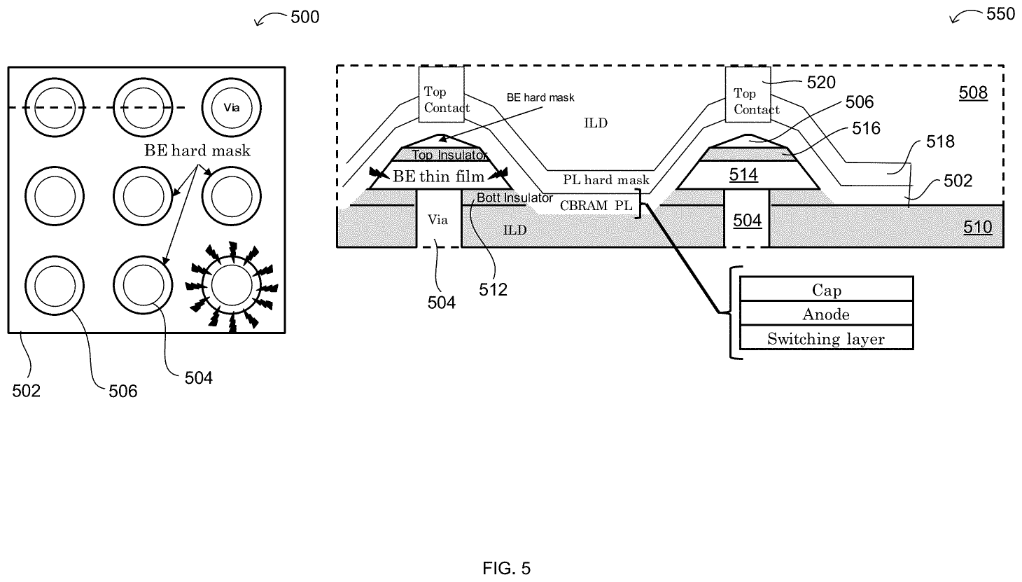

Referring now to FIG. 5, shown is a diagram of an example edge bottom electrode structure, in accordance with embodiments of the present invention. In this example, 500 shows a top view diagram of the cell plate layer 502 and via 504 arrangement, while example 550 shows a cross-section diagram. For example, bottom insulator 512 can be formed on a substrate ILD 510, and vias 504 can be formed in bottom insulator 512 and substrate ILD 510. The vias can include a via metal (e.g., Ta) and a flat via surface that may be in alignment with the top of bottom insulator 512. Bottom electrode 514 can be a thin film that fully covers each via 504 and at least a portion of bottom insulator 512. Also, top insulator 516 can be formed on bottom electrode 514. Bottom electrode hard mask 506 can be formed on top insulator 516. For example, the bottom electrode hard mask can be wider than the vias. Cell plate layer 502 can be in contact with bottom electrode hard mask 506, top insulator 516, bottom electrode 514, bottom insulator 512, and substrate ILD 510, and may cover one or more bottom electrodes. In addition, PL hard mask 518 can be on cell plate layer 502, and electrical contact 520 can be connected to the cell plate layer for subsequent connectivity. For example, cell plate layer 502 can include a switching layer (e.g., SiO₂, etc.), an anode layer (e.g., HfₓTe₁₋ₓ, etc.) and a cap layer (e.g., TaₓSi₁₋ₓ, etc.).

In the diagrams, the lightning bolt shapes may indicate the active area where switching can occur of one memory cell. In this structure, there may be less variability of the bottom electrode between memory cells because the active area may not be affected by the topography of the via surface, and the BE active area can be formed by etch instead of CMP. In addition, wafer-to-wafer and lot-to-lot variability can be lessened because the reproducibility of an etch process is typically better than that of a CMP process. Also, this approach can facilitate the use of alternate BE materials, and may present the opportunity to utilize a “pointy” BE or other suitable shapes by making BE layer very thin.

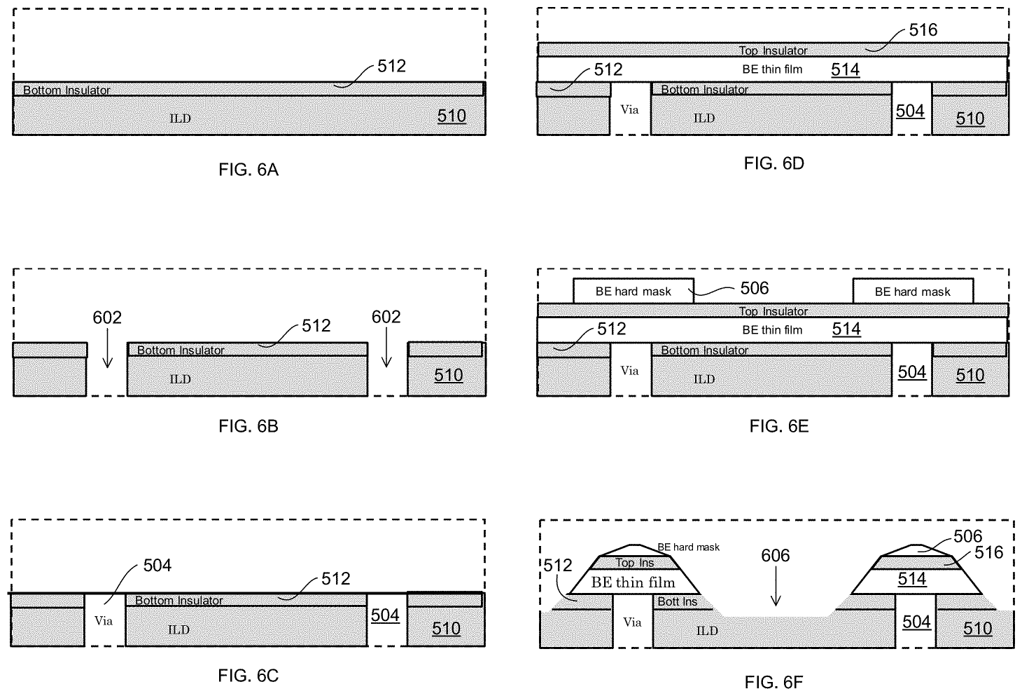

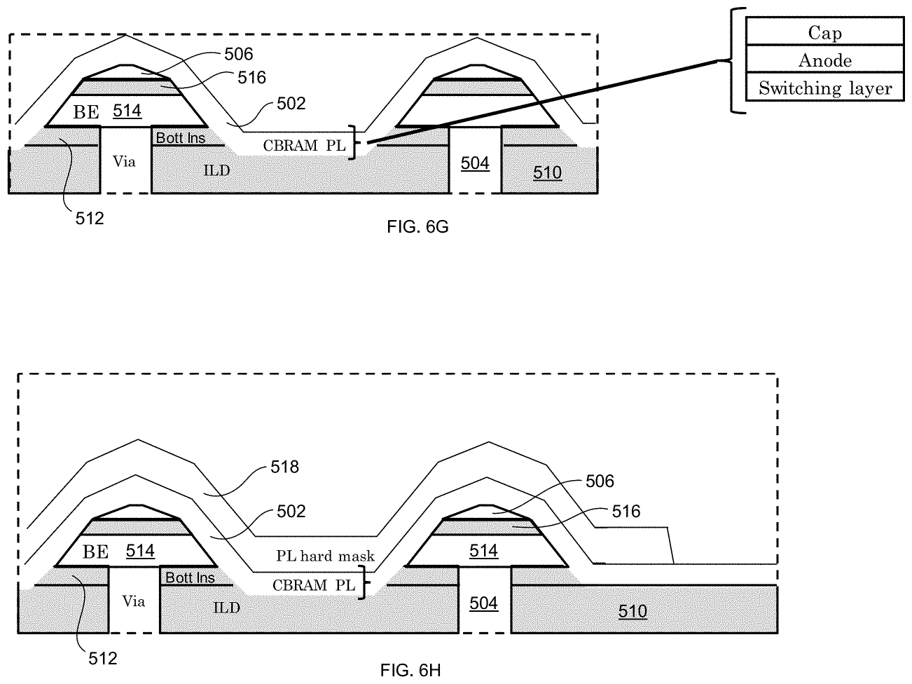

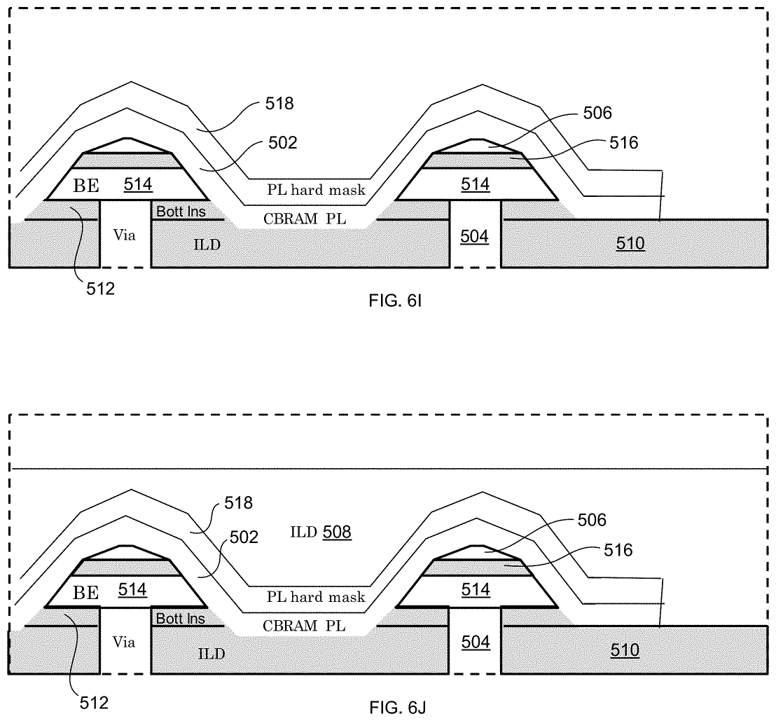

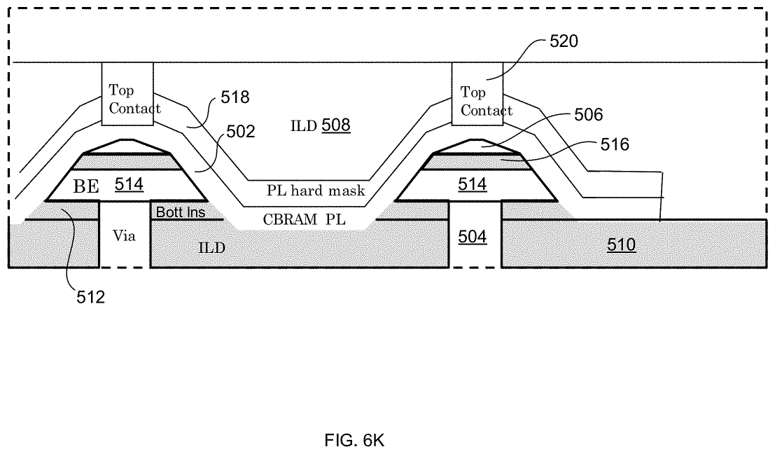

Referring now to FIGS. 6A-6K, shown are cross-section diagrams of an example process flow for making an edge bottom electrode structure, in accordance with embodiments of the present invention. In FIG. 6A, an optional bottom insulator 512 can be deposited on substrate ILD 510 in the back end of line (BEOL) of a standard silicon process. In FIG. 6B, vias can be formed in the substrate by patterning and etching holes 602 in bottom insulator 512 and substrate ILD 510. In FIG. 6C, the holes can be filled with a via metal (e.g., Ta), and then CMP can be used to produce a flat surface of via 504, such as in alignment with a top surface of bottom insulator 512. In one embodiment, the optional bottom insulator 512 and substrate 510 can be etched at the same time. In another embodiment, the optional bottom insulator 512 may be etched using a first etch process, and the substrate ILD 510 can then be etched using a second etch process.

In FIG. 6D, BE thin film 514 and top insulator 516 can be deposited. In FIG. 6E, the CBRAM bottom electrodes 506 can be defined, such as by depositing and patterning a BE hard mask layer as shown. In FIG. 6F, top insulator 516, BE thin film 514, and optional bottom insulator 512 can be etched 606. In some embodiments, the same thin film may be used as both the top insulator and the BE hard mask layer. In other embodiments whereby a BE hard mask layer is included but with no explicit top insulator, the BE hard mask layer may also serve as a top insulator. In FIG. 6G, a CBRAM plate (PL) 502 can be deposited, including a switching layer (e.g., SiO₂), an anode layer (e.g., HfₓTe₁₋ₓ), and a cap layer (e.g., TaₓSi₁₋ₓ).

In FIG. 6H, the CBRAM plate (PL) can be patterned, such as by depositing and patterning PL hard mask layer 518, and then etching the PL (see, e.g., FIG. 6I). For example, the CBRAM plate layer may cover one or more bottom electrodes. In some cases, the cell plate layer may span an array of CBRAM memory cells. In FIG. 6J, the CBRAM plate (PL) can be encapsulated, such as with an ILD (e.g., 508). In FIG. 6K, electrical contact can be made to the plate (PL), such as by forming top contacts/vias 520 through ILD layer 508.

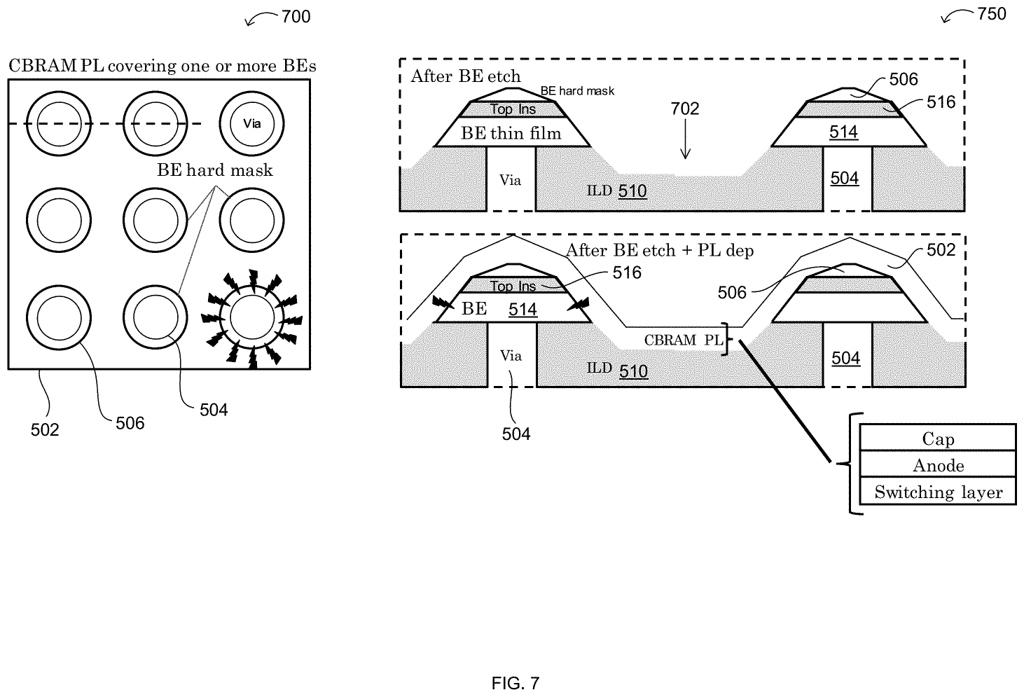

Referring now to FIG. 7, shown is a diagram of an example bottom electrode structure without a bottom insulator, in accordance with embodiments of the present invention. As discussed above, there may be less variability of the BE between memory cells in this approach because the active area may not be affected by the topography of the via surface, and the BE active area can be formed by etch instead of CMP. In addition, wafer-to-wafer and lot-to-lot variability can be lessened because the reproducibility of an etch process is typically better than that of a CMP process. This approach can also facilitate the use of alternate BE materials. Further, this approach may present the opportunity to utilize a “pointy” shaped BE by making BE layer very thin.

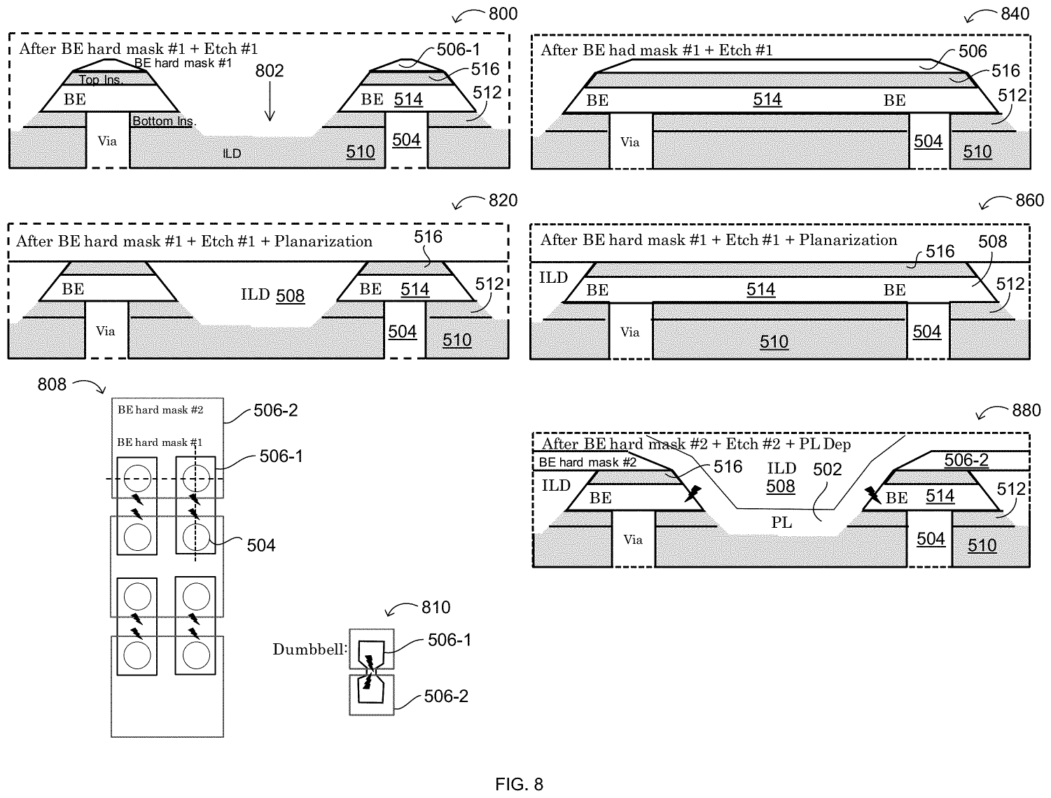

Referring now to FIG. 8, shown is a diagram of an example rectangular/dumbbell bottom electrode structure, in accordance with embodiments of the present invention. In this particular example, the switching layer oxide can by observed by transmission electron microscopy (TEM) directly on the active cells themselves without needing a companion TEM structure. Here, diagram 808 shows example layout structures of BE hard mask #1 (506-1) and BE hard mask #2 (506-2). For example, the BE hard mask #1 can be replaced by the dumbbell shape, as shown in 810, and the dumbbell structure can effectively reduce the size of the active area.

The diagrams 800 and 820 show an example cross-section of a process flow as viewed along the horizontal dashed line of diagram 808. In 800, the cross-section is shown after BE hard mask #1 and a first etch 802. In 820, planarization can be performed after BE hard mask 506-1 and the first etch. The diagrams 840, 860, and 880 show an example cross-section of a process flow as viewed along the vertical dashed line of diagram 808. In 840, the cross-section is shown after BE hard mask #1 and a first etch. At 860, planarization can be performed after BE hard mask 506-2 and a second etch. At 880, cell plate layer 502 can be deposited.

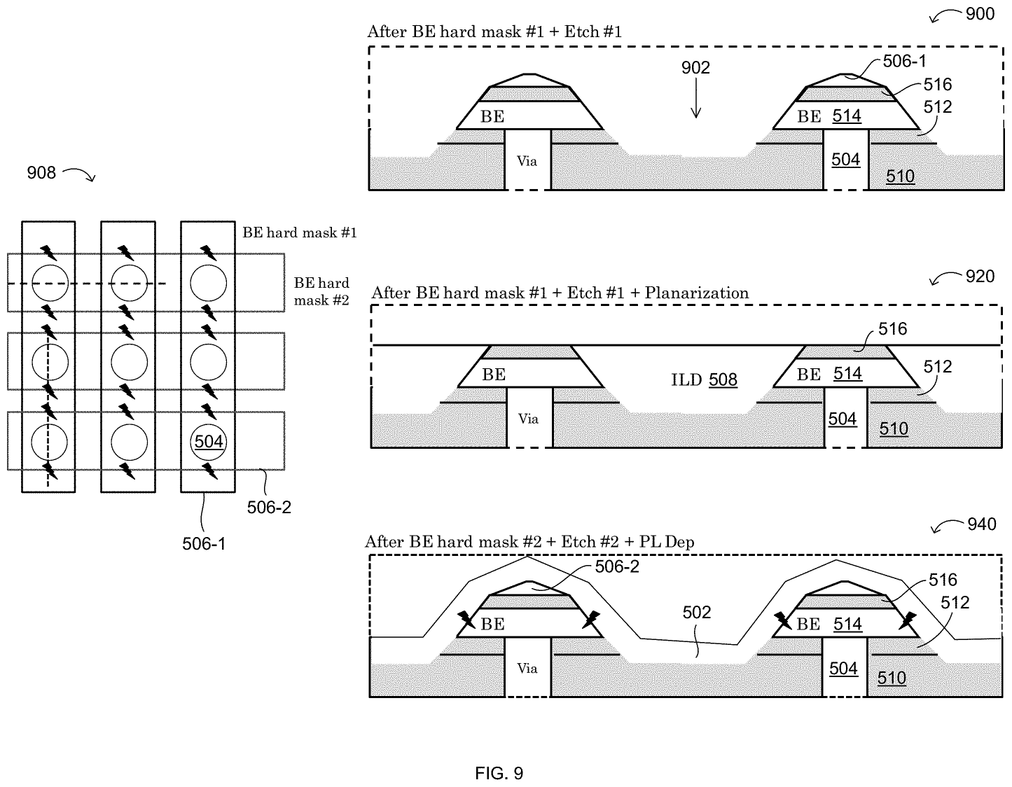

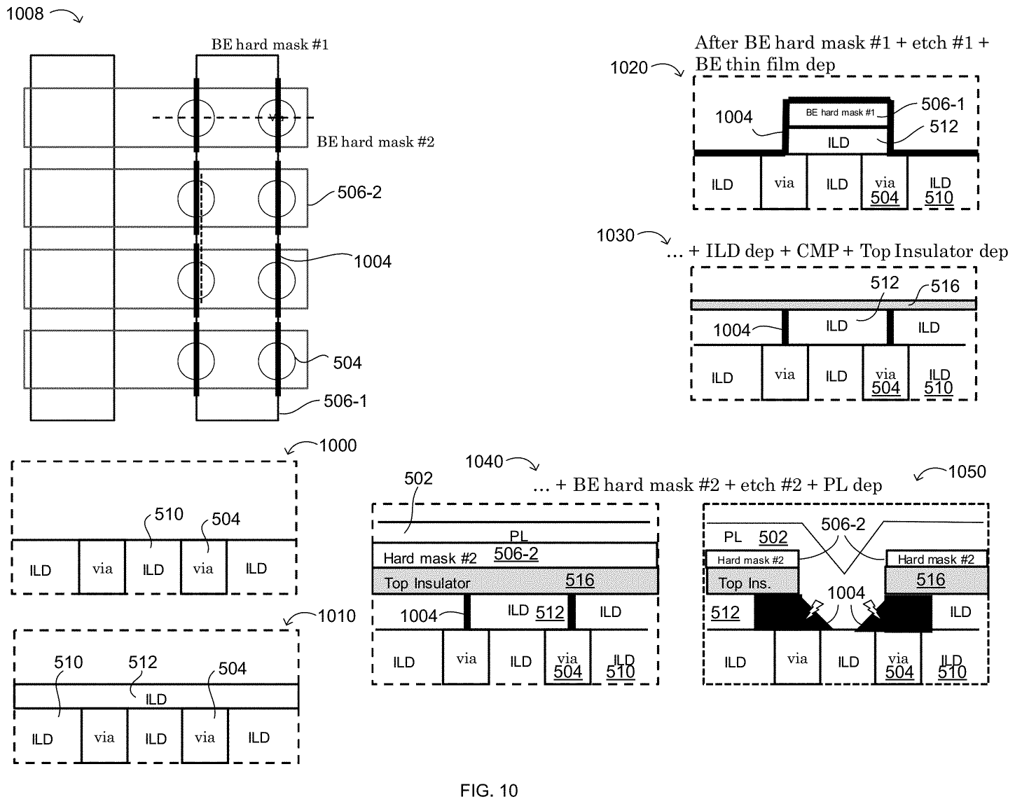

Referring now to FIG. 9, shown is a diagram of an example square bottom electrode structure, in accordance with embodiments of the present invention. This particular example may have advantages including all of the square cells being the same, which can facilitate mask production. Here, diagram 908 shows example layout structures of BE hard mask #1 (506-1) and BE hard mask #2 (506-2). The diagrams 900 and 920 show an example cross-section of a process flow as viewed along the horizontal dashed line of diagram 908. In 900, the cross-section is shown after BE hard mask #1 and a first etch 902. In 920, planarization can be performed after BE hard mask 506-1 and the first etch. The diagram 940 shows an example cross-section of a process flow as viewed along the vertical dashed line of diagram 908. In 940, the cross-section is shown after BE hard mask #2 and a second etch, and deposition of cell plate layer 502.

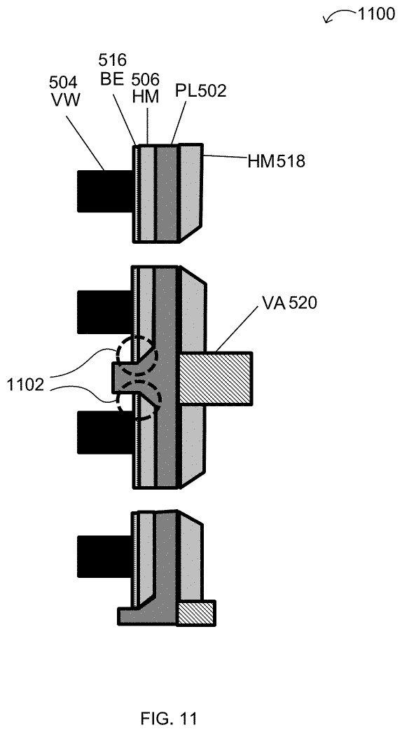

Referring now to FIG. 10, shown is a diagram of an example sidewall bottom electrode structure, in accordance with embodiments of the present invention. FIGS. 11-13 show further examples of the formation and structure of the sidewall bottom electrode. In FIG. 10, diagram 1008 shows example layout structures of BE hard mask #1 (506-1) and BE hard mask #2 (506-2), as well as BE thin film 1004. The diagrams 1000, 1010, 1020, 1030, and 1040 show an example cross-section of a process flow as viewed along the horizontal dashed line of diagram 1008. In 1000, the via 504 and substrate ILD 510 arrangement as shown. In 1010, ILD 512 can be deposited. In 1020, after BE hard mask 506-1 and a first etch, BE thin film 1004 can be deposited. In 1030, after ILD deposition and CMP, top insulator 516 can be deposited. In 1040, after BE hard mask 506-2 and a second etch, cell plate layer 502 can be deposited. The diagram 1050 shows an example cross-section of a process flow as viewed along the vertical dashed line of diagram 1008. In 1050, after BE hard mask 506-2 and a second etch, cell plate layer 502 can be deposited to form a sidewall bottom electrode structure.

Referring now to FIG. 11, shown is a diagram of an example structure corresponding to a layout of the sidewall bottom electrode structure, in accordance with embodiments of the present invention. Diagram 1100 shows sidewall bottom electrode portions 1102. As shown, via 504 can be covered by bottom electrode 514. BE hard mask 506 can be on bottom electrode thin film 514. Cell plate layer 502 can cover BE hard mask 506, and PL hard mask 518 can cover cell plate layer 502. Also, top contact/via 520 can connect to cell plate layer 502 to allow for subsequent electrical connectivity.

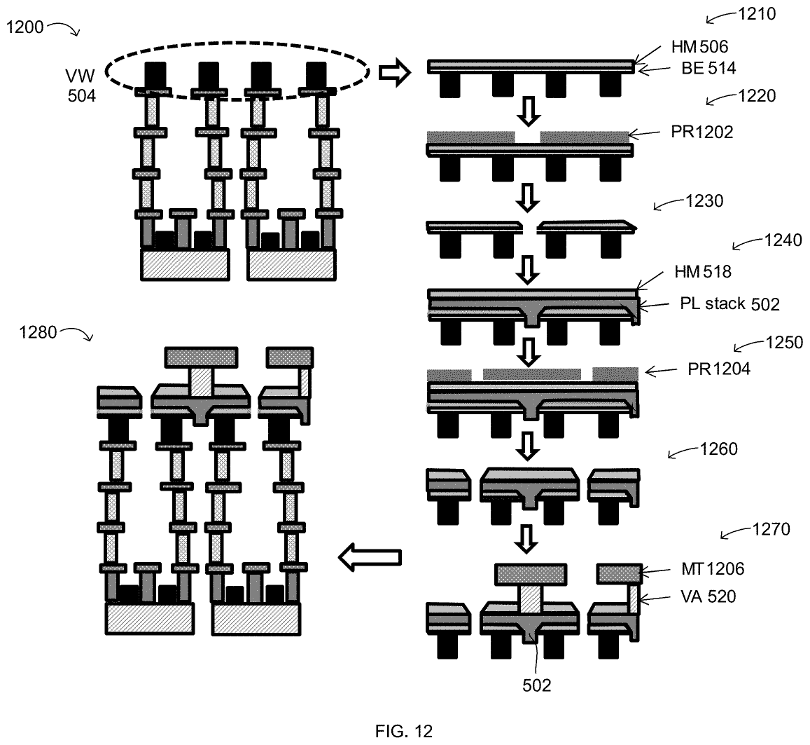

Referring now to FIG. 12, shown is a diagram of an example process flow of the sidewall bottom electrode structure, in accordance with embodiments of the present invention. Diagram 1200 shows vias 504, and subsequent steps show a BEOL process flow after formation of vias 504. In 1210, bottom electrode thin film 514 can be deposited, and BE hard mask 506 can be deposited on BE thin film 514. In 1220, photoresist 1202 can be deposited and patterned. In 1230, etching can be performed using the photoresist to accommodate the BE sidewall structure. In 1240, PL stack 502 (e.g., cap, anode, switching layer) can be deposited, and PL hard mask 518 can be deposited on PL stack 502. In 1250, photoresist 1204 can be deposited and patterned. In 1260, etching through hard mask 518, PL stack 502, BE hard mask 506, and BE thin film 514 can occur. In 1270, top contacts/vias 520 can be deposited, and metal layer 1206 can be deposited and may connect with contacts/vias 520. Diagram 1280 shows the completed cross-section including cell plate layer 502 with sidewall bottom electrode structure.

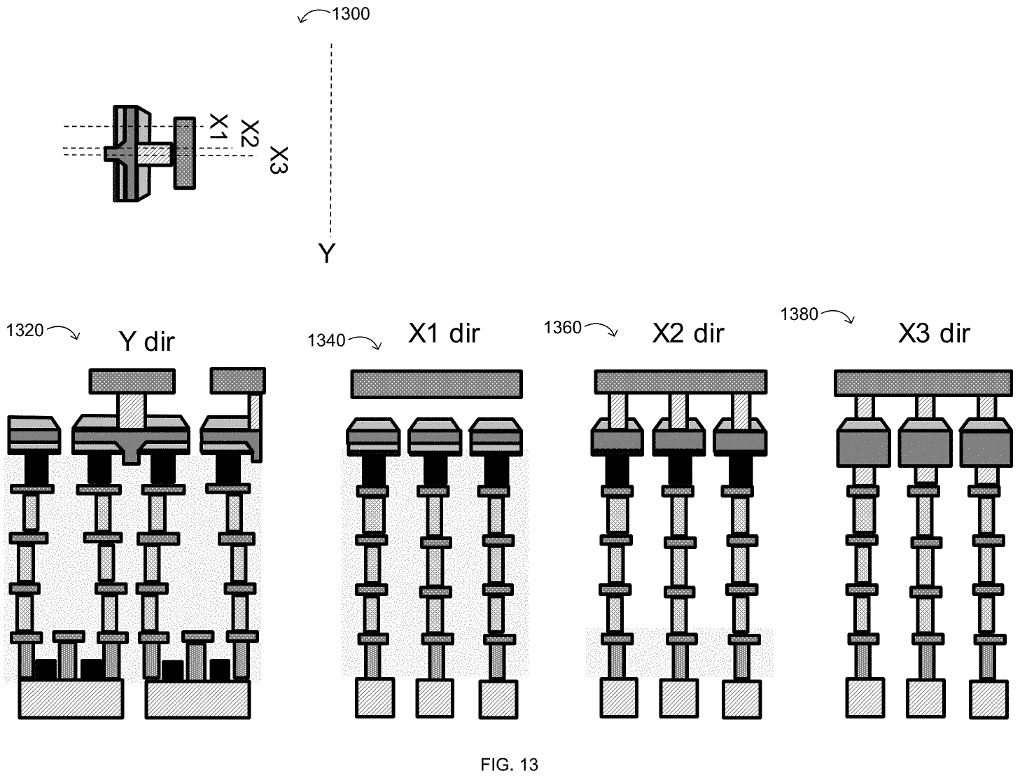

Referring now to FIG. 13, shown is a cross-sectional diagram of the example sidewall bottom electrode structure, in accordance with embodiments of the present invention. Diagram 1300 shows a cell with direction indicators for the subsequent cross-section diagrams. In 1320, a cross-section diagram along the Y direction shows cell plate layer 502 with sidewall bottom electrode structure, top contact via 520, and metal layer 1206. In 1340, a cross-section diagram along the X1 direction is shown. In 1360, a cross-section diagram along the X2 direction is shown. In 1380, a cross-section diagram along the X3 direction is shown.

In contact area calculation of the sidewall bottom electrode structure, any such values and process geometries can be supported in certain embodiments. They may generally be 2 options as to the masks to be taped out in support of forming the sidewall bottom electrode structure. In a first option, the masks can include a VY mask used to define trench, a PL mask used to define an island (e.g., 2 cells/island), a VL mask used for VA to each island, and an MT mask. In a second option, a VY mask can be used to define an island (e.g., 1 cell/island).

While the above examples include circuit, operational, and structural implementations of certain memory arrangements and devices, one skilled in the art will recognize that other technologies and/or architectures, as well as other modes of operation, can be used in accordance with embodiments. Further, one skilled in the art will recognize that other device circuit arrangements, architectures, elements, and the like, may also be used in accordance with embodiments. The foregoing descriptions of specific embodiments of the present invention have been presented for purposes of illustration and description. They are not intended to be exhaustive or to limit the invention to the precise forms disclosed, and obviously many modifications and variations are possible in light of the above teaching. The embodiments were chosen and described in order to best explain the principles of the invention and its practical application, to thereby enable others skilled in the art to best utilize the invention and various embodiments with various modifications as are suited to the particular use contemplated. It is intended that the scope of the invention be defined by the claims appended hereto and their equivalents.

What is claimed is:

1. A method of forming bottom electrodes in a resistive memory device, the method comprising:
a) depositing a bottom insulator on a substrate interlayer dielectric (ILD);
b) forming vias in the substrate ILD by patterning and etching holes in the bottom insulator and the substrate ILD;
c) filling the holes with a via metal to form a flat via surface;
d) depositing a bottom electrode thin film and a top insulator;
e) defining the bottom electrode;
f) etching the top insulator, the bottom electrode thin film, and the bottom insulator;
g) depositing a cell plate layer having a switching layer, an anode layer, and a cap layer;
h) patterning the cell plate layer by depositing and patterning a cell plate hard mask layer, and then etching the cell plate layer;
i) encapsulating the cell plate layer; and
j) forming electrical contact to the cell plate layer.

2. The method of claim 1, wherein the depositing the bottom insulator comprises a back end of line (BEOL) of a standard silicon process.

3. The method of claim 1, wherein the bottom insulator and the substrate are etched at a same time.

4. The method of claim 1, wherein the bottom insulator is etched using a first etch process, and the substrate is then etched using a second etch process.

5. The method of claim 1, wherein the defining the bottom electrodes comprises depositing and patterning a bottom electrode hard mask layer.

6. The method of claim 5, wherein a same thin film is used as both the top insulator and the bottom electrode hard mask layer.

7. The method of claim 1, wherein the switching layer comprises SiO₂, the anode layer comprises HfₓTe₁₋ₓ, and the cap layer comprises TaₓSi₁₋ₓ.

8. The method of claim 1, wherein the cell plate layer covers one or more bottom electrodes.

9. The method of claim 1, wherein the encapsulating the cell plate layer comprises using an ILD layer.

10. The method of claim 9, wherein the making electrical contact to the cell plate layer comprises forming top contacts or vias through the ILD layer.

11. The method of claim 1, wherein a shape of each of the bottom electrodes is rounded.

12. The method of claim 1, wherein a shape of each of the bottom electrodes is rectangular or dumbbell.

13. The method of claim 1, wherein each of the bottom electrodes comprises a sidewall.

14. A resistive memory device, comprising:
a) a bottom insulator on a substrate interlayer dielectric (ILD);
b) vias in the bottom insulator and the substrate ILD, the vias having a via metal and a flat via surface;
c) a bottom electrode fully covering the vias and at least a portion of the bottom insulator;
d) a top insulator on the bottom electrode;
e) a bottom electrode hard mask on the top insulator, wherein the bottom electrode hard mask is wider than the vias;
f) a cell plate layer in contact with the bottom electrode hard mask, the top insulator, the bottom electrode, the bottom insulator, and the substrate ILD; and
g) an electrical contact connected to the cell plate layer.

15. The resistive memory device of claim 14, wherein the switching layer comprises SiO₂, the anode layer comprises HfₓTe₁₋ₓ, and the cap layer comprises TaₓSi₁₋ₓ.

16. The resistive memory device of claim 14, wherein each of the bottom electrodes comprises a sidewall.

17. The resistive memory device of claim 14, wherein the cell plate layer covers one or more bottom electrodes.

18. The resistive memory device of claim 14, wherein the cell plate layer is encapsulated by an ILD layer, and electrical contact to the cell plate layer is made by top contacts or vias through the ILD layer.

19. The resistive memory device of claim 14, wherein a shape of each of the bottom electrodes is rounded.

20. The resistive memory device of claim 14, wherein a shape of each of the bottom electrodes is rectangular or dumbbell.
